(19) United States
(12) Patent Application Publication
(10) Pub. No.: US 2024/0143026 A1
(43) Pub. Date: May 2, 2024

(54) DISPLAY APPARATUS

(71) Applicant: LG Display Co., Ltd., Seoul (KR)

(72) Inventors: Kelly Sooyeun SONG, Goyang-si (KR); MinHo LEE, Geoje-si (KR); Giyoun KIM, Goyang-si (KR)

(73) Assignee: LG Display Co., Ltd., Seoul (KR)

(21) Appl. No.: 18/220,680

(22) Filed: Jul. 11, 2023

(30) Foreign Application Priority Data
Oct. 28, 2022 (KR) 10-2022-0141019

(51) Int. Cl. G06F 1/16; H04M 1/02

(52) U.S. Cl. CPC G06F 1/1616; G06F 1/1652; G06F 1/1656; H04M 1/0216; H04M 1/0268

(57) ABSTRACT

A display apparatus can include a display panel including a folding area and a non-folding area adjacent to the folding area. The display apparatus can further include a supporting substrate disposed below the display panel, and including a plurality of opening patterns corresponding to the folding area, and a plurality of hole patterns or a plurality of groove patterns corresponding to the non-folding area.

### CROSS-REFERENCE TO RELATED APPLICATIONS

This application claims priority to Korean Patent Application No. 10-2022-0141019 filed on Oct. 28, 2022, in the Republic of Korea, the entire contents of which are hereby expressly incorporated by reference into the present application.

### BACKGROUND OF THE DISCLOSURE

### Field

The present disclosure relates to a display apparatus.

### Discussion of the Related Art

Recently, as the society enters a full-scale information era, a field of a display apparatus which processes and displays a large number information has been rapidly developed. Among the display apparatuses that can be used for a monitor of a computer, a television, or a cellular phone, there are an organic light emitting display (OLED) apparatus which is a self-emitting device and a liquid crystal display (LCD) apparatus which requires a separate light source.

An applicable range of the display apparatus is rather large and diverse, which can include personal digital assistants as well as monitors of computers and televisions. As such, a display apparatus with a large display area and a reduced volume and weight is being studied.

Recently, a flexible display apparatus which is manufactured to be capable of displaying images even though the flexible display apparatus is bent or folded like paper is attracting attention as the next generation display apparatus. The flexible display apparatus can utilize a plastic substrate rather than glass to be classified into a display device having a high durability, a bendable display apparatus which is bent without being broken, a rollable display apparatus which is rolled, and a foldable display apparatus which is folded. Such a flexible display apparatus has advantages in terms of space utilization, decoration, and designs and has various application fields.

### SUMMARY OF THE DISCLOSURE

In a flexible display apparatus, due to a consistent folding in the bendable structure, a surface deformation issue can occur and the visibility and the touch sense can be degraded due to the waviness.

Accordingly, the inventors of the present disclosure recognized the above-mentioned limitations and conducted extensive research and experiments to relieve the waviness phenomenon which can be caused by the bending of the display apparatus and to improve a performance of the display apparatus. The inventors invented a new display apparatus which can minimize a surface deformation issue of the display apparatus and improve the performance of the display apparatus through extensive research and experiments.

One or more aspects of the present disclosure are to provide a display apparatus which minimizes an appearance deformation issue which may be caused by repeated bending.

One or more aspects of the present disclosure are to provide a display apparatus which improves an appearance deformation issue while maintaining some degree of an adhesiveness with an adhesive layer.

To achieve these and other advantages and aspects and in accordance with the purpose of the present disclosure, as embodied and broadly described herein, a display apparatus can include a folding area a non-folding area adjacent to the folding area; and a supporting substrate disposed below the display panel, the supporting substrate including a plurality of opening patterns corresponding to the folding area, and a plurality of hole patterns or a plurality of groove patterns corresponding to the non-folding area.

According to an exemplary embodiment of the present disclosure, a hole pattern is formed in a non-folding area of a supporting substrate to be filled with a polymer in which shape memory materials are dispersed, thereby reliving the deformation. Thus, a step difference between the adhesive layer and the supporting substrate due to the bending is minimized to relieve a waviness phenomenon of the folding area.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain the principles of the disclosure.

FIG. 1 illustrates a planar structure of a display apparatus according to a first exemplary embodiment of the present disclosure.

FIG. 2 illustrates a cross-sectional structure of a display apparatus according to the first exemplary embodiment of the present disclosure.

FIG. 3 illustrates a cross-sectional structure of a display panel of a display apparatus.

FIG. 4 is a plan view illustrating a structure of a supporting substrate of a display apparatus according to the first exemplary embodiment of the present disclosure.

FIG. 5 is a view enlarging a part A of FIG. 4 according to the first exemplary embodiment of the present disclosure.

FIGS. 6A to 6D illustrate different examples of a shape of a hole pattern according to an embodiment of the present disclosure.

FIGS. 7A to 7C illustrate various examples of a supporting substrate according to a second exemplary embodiment of the present disclosure.

FIG. 8 illustrates a cross-sectional structure of a display apparatus according to a third exemplary embodiment of the present disclosure.

FIG. 9 is a plan view illustrating a structure of a supporting substrate of a display apparatus according to the third exemplary embodiment of the present disclosure.

FIG. 10 is a plan view illustrating a structure of a supporting substrate of a display apparatus according to a fourth exemplary embodiment of the present disclosure.

FIG. 11 illustrates a cross-sectional structure of a display apparatus according to a fifth exemplary embodiment of the present disclosure.

FIG. 12 illustrates a cross-sectional structure of a display apparatus according to a sixth exemplary embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof can be exaggerated for clarity, illustration, and convenience.

### DETAILED DESCRIPTION OF THE EMBODIMENTS

Reference is now made in detail to embodiments of the present disclosure, examples of which can be illustrated in the accompanying drawings. In the following description, when a detailed description of well-known functions or configurations can unnecessarily obscure aspects of the present disclosure, the detailed description thereof can be omitted for brevity. The progression of processing steps and/or operations described is an example; however, the sequence of steps and/or operations is not limited to that set forth herein and can be changed, with the exception of steps and/or operations necessarily occurring in a particular order.

Advantages and features of the present disclosure, and implementation methods thereof, are clarified through the example embodiments described with reference to the accompanying drawings. The present disclosure may, however, be embodied in different forms and should not be construed as limited to the example embodiments set forth herein. Rather, these example embodiments are examples and are provided so that this disclosure can be thorough and complete to assist those skilled in the art to fully understand the present disclosure without limiting the protected scope of the present disclosure.

The shapes, sizes, areas, ratios, angles, numbers, and the like disclosed in the drawings for describing various example embodiments of the present disclosure are merely an example, and thus, the present disclosure is not limited to the illustrated details. Like reference numerals refer to like elements throughout.

Where the term “comprise,” “have,” “include,” “contain,” “constitute,” “make up of,” “formed of,” or the like is used, one or more other elements can be added unless the term, such as “only” or the like is used. The terms used in the present disclosure are merely used in order to describe particular embodiments, and are not intended to limit the scope of the present disclosure. The terms used herein are merely used in order to describe example embodiments, and are not intended to limit the scope of the present disclosure. The terms of a singular form can include plural forms unless the context clearly indicates otherwise. The word “exemplary” is used to mean serving as an example or illustration. Embodiments are example embodiments. Aspects are example aspects. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range can be caused by various factors (e.g., process factors, internal or external impact, noise, or the like). Further, the term “may” encompasses all the meanings of the term “can.”

In describing a positional relationships, where the positional relationship between two parts is described, for example, using on,” “over,” “under,” “above,” “below,” “beneath,” “near,” “close to,” or “adjacent to,” “beside,” “next to,” or the like, one or more other parts can be located between the two parts unless a more limiting term, such as “immediate(ly),” “direct(ly),” or “close(ly),” is used.

For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which one or more additional structures are disposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as, for example, “after,” “subsequent,” “next,” and “before,” “preceding,” “prior to,” or the like a case that is not consecutive or not sequential can be included unless a more limiting term, such as “just,” “immediate(ly),” or “direct(ly)” is used.

It will be understood that, although the term “first,” “second,” or the like can be used herein to describe various elements, these elements should not be limited by these terms. These terms are only used to distinguish one element from another. For example, a first element could be a second element, and, similarly, a second element could be a first element, without departing from the scope of the present disclosure. Furthermore, the first element, the second element, and the like can be arbitrarily named according to the convenience of those skilled in the art without departing from the scope of the present disclosure. The terms “first,” “second,” and the like can be used to distinguish components from each other, but the functions or structures of the components are not limited by ordinal numbers or component names in front of the components.

In describing the elements of the present disclosure, the terms “first,” “second,” “A,” “B,” “(a),” “(b),” or the like can be used. These terms are intended to identify the corresponding element(s) from the other element(s), and these are not used to define the essence, basis, order, or number of the elements.

For the expression that an element is “connected,” “coupled,” “attached,” or “adhered” to another element or layer the element or layer can not only be directly connected, coupled, attached, or adhered to another element or layer, but also be indirectly connected, coupled, attached, or adhered to another element or layer with one or more intervening elements or layers disposed or interposed between the elements or layers, unless otherwise specified. For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as only one of the first item, the second item, or the third item.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C. Furthermore, an expression “element A/element B” can be understood as element A and/or element B.

In one or more aspects, the terms “between” and “among” can be used interchangeably simply for convenience unless stated otherwise. For example, an expression “between a plurality of elements” can be understood as among a plurality of elements. In another example, an expression “among a plurality of elements” can be understood as between a plurality of elements. In one or more examples, the number of elements can be two. In one or more examples, the number of elements can be more than two.

In one or more aspects, the phrases “each other” and “one another” can be used interchangeably simply for convenience unless stated otherwise. For example, an expression “different from each other” can be understood as being different from one another. In another example, an expression “different from one another” can be understood as being different from each other. In one or more examples, the number of elements involved in the foregoing expression can be two. In one or more examples, the number of elements involved in the foregoing expression can be more than two. In one or more aspects, the phrases “one or more among” and “one or more of” can be used interchangeably simply for convenience unless stated otherwise.

In the present disclosure, examples of a display apparatus can include a narrow-sense display apparatus such as a quantum dot (QD) module, an organic light emitting diode (OLED) module or a liquid crystal module (LCM) having a display panel and a driver for driving the display panel. Further, examples of the display apparatus can include a set device (or a set apparatus) or a set electronic apparatus such as a notebook computer, a TV, a computer monitor, an equipment apparatus including an automotive apparatus or another type of apparatus for vehicles, or a mobile electronic device such as a smartphone or an electronic pad, which is a complete product (or a final product) including an LCM, an OLED module, and a QD module.

Therefore, in the present disclosure, examples of the display apparatus can include a narrow-sense display apparatus itself, such as an LCM, an OLED module, and a QD module, and a set apparatus, which is a final consumer apparatus or an application product including the LCM, the OLED module, and the QD module.

In some embodiments, an LCM, an OLED module, and a QD module including a display panel and a driver can be referred to as a narrow-sense display apparatus, and an electronic apparatus, which is a final product including an LCM, an OLED module, and a QD module can be referred to as a set apparatus. For example, the narrow-sense display apparatus can include a display panel, such an LCM, an OLED module, or a QD module, and a source printed circuit board (PCB), which is a controller for driving the display panel. The set apparatus can further include a set PCB, which is a set controller electrically connected to the source PCB to overall control the set apparatus.

A display panel applied to embodiments of the present disclosure can use any type of display panel, including a liquid crystal display panel, an organic light emitting diode (OLED) display panel, a quantum dot (QD) display panel, and an electroluminescent display panel. The display panel of embodiments of the present disclosure is not limited to a specific display panel capable of bezel bending with a flexible substrate for an organic light emitting diode (OLED) display panel and a lower back plate support structure. Further, a shape or a size of a display panel applied to a display apparatus according to one or more embodiments of the present disclosure is not limited.

In an example where the display panel is the organic light emitting display panel, the display panel can include a plurality of gate lines, data lines, and pixels respectively provided in intersections of the gate lines and the data lines. Further, the display panel can include an array including a thin film transistor (TFT), which is an element for selectively applying a voltage to each of the pixels, a light emitting element layer on the array, and an encapsulation substrate or an encapsulation layer disposed on the array to cover the light emitting element layer. The encapsulation substrate can protect the TFT and the light emitting element layer from an external impact and can prevent water or oxygen from penetrating into the light emitting element layer. Further, a layer provided on the array can include an inorganic light emitting layer, for example, a nano-sized material layer, a quantum dot, or the like.

Features of various embodiments of the present disclosure can be partially or wholly coupled to or combined with each other, and can be variously inter-operated, linked or driven together. Embodiments of the present disclosure can be carried out independently from each other, or can be carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements can be illustrated in other drawings, and like reference numerals can refer to like elements unless stated otherwise. In addition, for convenience of description, a scale, dimension, size, and thickness of each of the elements illustrated in the accompanying drawings can be different from an actual scale, dimension, size, and thickness, and thus, embodiments of the present disclosure are not limited to a scale, dimension, size, and thickness illustrated in the drawings.

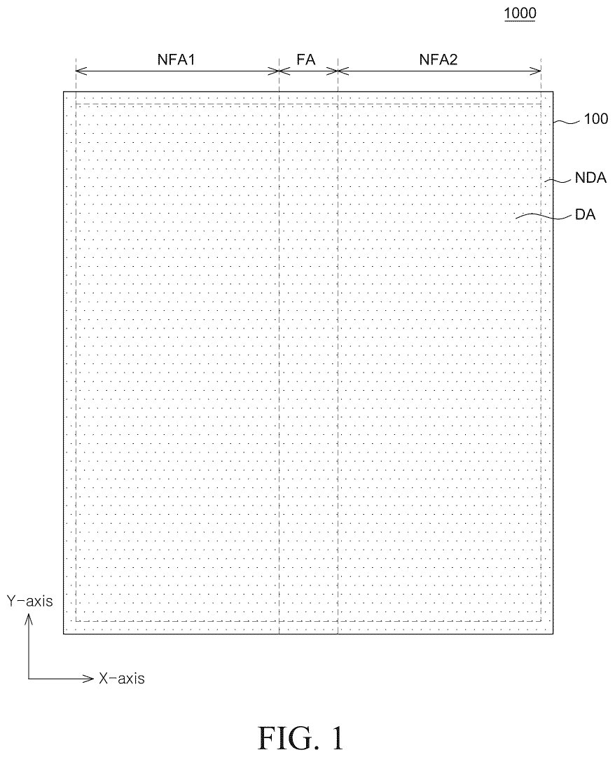

FIG. 1 illustrates a planar structure of a display apparatus according to a first exemplary embodiment of the present disclosure.

Referring to FIG. 1, a display apparatus 1000 according to the first exemplary embodiment of the present disclosure can include a display panel 100 including a display area DA and a non-display area NDA.

Further, the display panel 100 can include a folding area FA and non-folding areas NFA1 and NFA2 excluding the folding area FA.

For example, the display panel 100 refers to any type of display substrates which display images using a transistor circuit. The display apparatus 1000 according to the first exemplary embodiment of the present disclosure can be implemented by an organic light emitting display apparatus. However, embodiments of the present disclosure are not limited thereto and the display apparatus 1000 according to the first exemplary embodiment of the present disclosure can be applied to a quantum dot display apparatus and a micro light emitting diode (μ-LED) display apparatus.

A substrate of the display panel 100 according to the first exemplary embodiment of the present disclosure can be a flexible substrate. For example, the substrate can be formed of a polymer material such as polyimide (PI) or a plastic material.

The display area DA can be provided on an entire surface of the display panel 100.

The display area DA is an area where a plurality of sub pixels is disposed to display images.

In the display area DA, sub pixels including a light emitting device configured to emit light and a driving circuit configured to drive the sub pixels can be disposed. The sub pixel is a configuration for displaying one color, and can include an emission area in which light is emitted and a non-emission area in which light is not emitted.

The plurality of sub pixels of the display area DA can configure a pixel, and the plurality of pixels including the plurality of sub pixels can substantially display images.

The non-display area NDA can be disposed in an outer periphery of the display area DA so as to surround the display area DA. For example, the non-display area NDA can be disposed so as to surround the display area DA. The non-display area NDA is an area in which the images are not substantially displayed and in the non-display area NDA, various circuits to supply a driving signal and a driving voltage to display images in the display area DA can be provided.

In the non-display area NDA, various wiring lines, driving ICs, and printed circuit boards for driving the pixels and the driving circuit disposed in the display area DA are disposed. For example, in the non-display area NDA, various ICs, such as a gate driver IC and a data driver IC, and VSS lines can be disposed.

The folding area FA is an area which is folded (or bent) when the display apparatus 1000 is folded (or bent), and the display panel 100 can be folded or bent along a specific radius of curvature with respect to a folding axis. For example, the folding area FA is an area in which the display panel 100 can be folded or bent. The folding area FA can include the display area DA and the non-display area NDA.

The folding area FA can be formed to traverse the display area DA and the non-display area NDA. For example, when the display panel 100 is folded or bent, the folding area can be formed from one corner of the display panel 100 to the other corner. In this case, the folding area FA can be formed to traverse one portion to the other portion of the display area DA from an outer periphery (or an outer edge) of the non-display area NDA.

For example, when a center portion of the display panel 100 is folded, the folding area FA can be formed to traverse the center portions of the display area DA and the non-display area NDA.

The non-folding areas NFA1 and NFA2 are areas which are not folded when the display apparatus 1000 is folded. For example, the non-folding areas NFA1 and NFA2 can maintain the flat state when the display apparatus 1000 is folded. The non-folding areas NFA1 and NFA2 can be disposed on both portions of the folding area FA. For example, when the folding axis of the folding area FA is formed in a Y-axis direction, the non-folding areas NFA1 and NFA2 can be areas which extend from the folding area FA to an X-axis direction which is perpendicular to the folding axis. For example, the folding area FA can be formed between two adjacent non-folding areas NFA1 and NFA2.

When the display apparatus 1000 is folded, the folding area FA is folded with respect to the folding axis, and the folding area FA can form a part of a circle or an oval. A radius of curvature of the folding area FA can be a radius of a circle or an oval formed by the folding area FA. When the folding area FA is folded with respect to the folding axis, the non-folding areas NFA1 and NFA2 can overlap each other.

The non-folding areas NFA1 and NFA2 can include a first non-folding area NFA1 and a second non-folding area NFA2 which are disposed so as to correspond to both edges (or both surrounding areas or both perimeter areas or both peripheries) of an opening pattern formed on the supporting substrate disposed below the display panel 100. When the folding area FA is folded with respect to the folding axis, the first non-folding area NFA1 and the second non-folding area NFA2 can overlap to face each other.

The display apparatus 1000 according to the first exemplary embodiment of the present disclosure includes the display area DA including a plurality of unit pixels configured by a plurality of sub pixels and a non-display area NDA which surrounds the display area DA. Further, the display apparatus 1000 can include a folding area FA defined in the display area DA and the non-display area NDA and non-folding areas NFA1 and NFA2 on both portions of the folding area FA.

Further, the display apparatus 1000 according to the first exemplary embodiment of the present disclosure can further include a folding boundary area between the folding area FA and the non-folding areas NFA1 and NFA2. For example, a first folding boundary area can be included between the folding area FA and the first non-folding area NFA1, and a second folding boundary area can be included between the folding area FA and the second non-folding area NFA2.

In a display apparatus of the related art, due to a repeated folding in the bendable structure, a surface deformation issue can occur and a visibility and a touch sense can be degraded due to the waviness.

The inventors of the present disclosure found that a main cause of a waviness shape of the folding area in a structure of the display apparatus in which the bending occurs was or can be the deformation of the adhesive layer. For example, to implement predetermined bending, a supporting substrate in the folding area was produced with a relative soft material so that it was confirmed that a waviness phenomenon affected by the deformation of the other layers located above the supporting substrate, for example, the deformation of the adhesive layer was or can be visible. A degree of contraction and expansion of each layer varies so that the creased waviness phenomenon can be generated due to the step difference generated between the layers.

The step difference between the layers can degrade the durability of the components which can cause bubbles between the folding area and the layers adjacent to the folding area. Further, there can be a limitation in that the opening pattern of the supporting substrate disposed in the folding area is visible due to a stress to be applied by the bending.

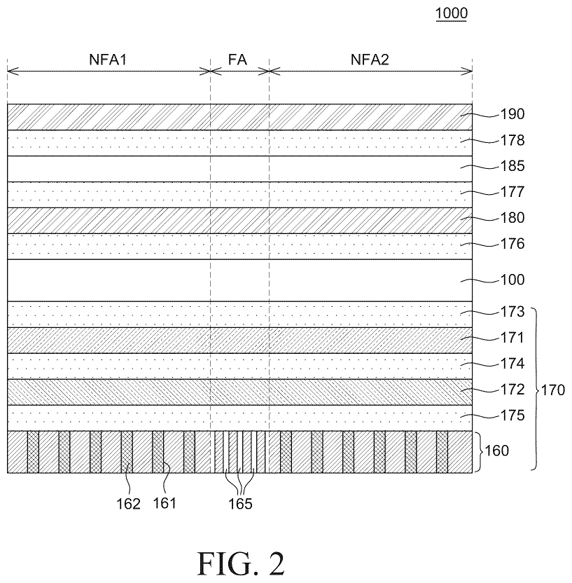

Therefore, the inventors of the present disclosure recognized the above-mentioned problems or limitations. However, since the layers deformed by the waviness phenomenon were not voluntarily restored, the inventors invented a new display apparatus 1000 in which a hole pattern was formed in the non-folding areas NFA1 and NFA2 of the supporting substrate to be filled with a polymer in which shape memory materials were dispersed. Thus, the deformation was restored effectively to relieve the waviness phenomenon of the folding area FA due to the bending. This will be described in more detail with reference to FIGS. 2 to 5.

FIG. 2 illustrates a cross-sectional structure of a display apparatus according to the first exemplary embodiment of the present disclosure.

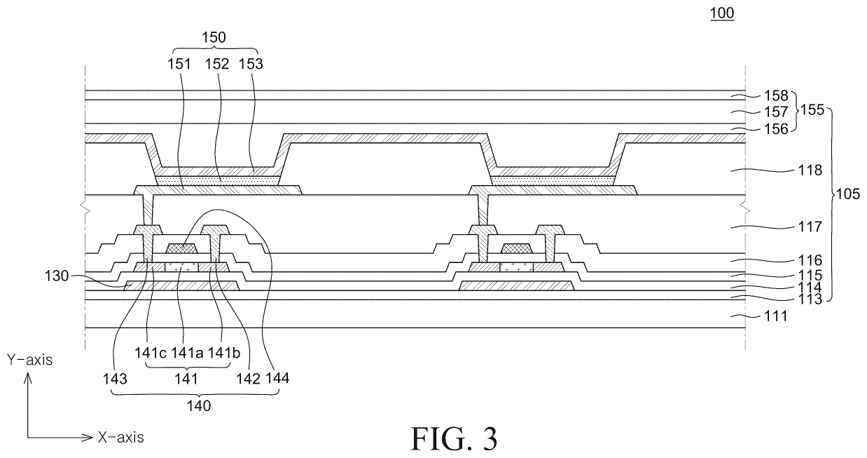

FIG. 3 illustrates a cross-sectional structure of a display panel of a display apparatus.

For example, FIG. 3 illustrates a cross-section of two sub pixels of a display panel 100 of a display apparatus 1000 according to the first exemplary embodiment of the present disclosure.

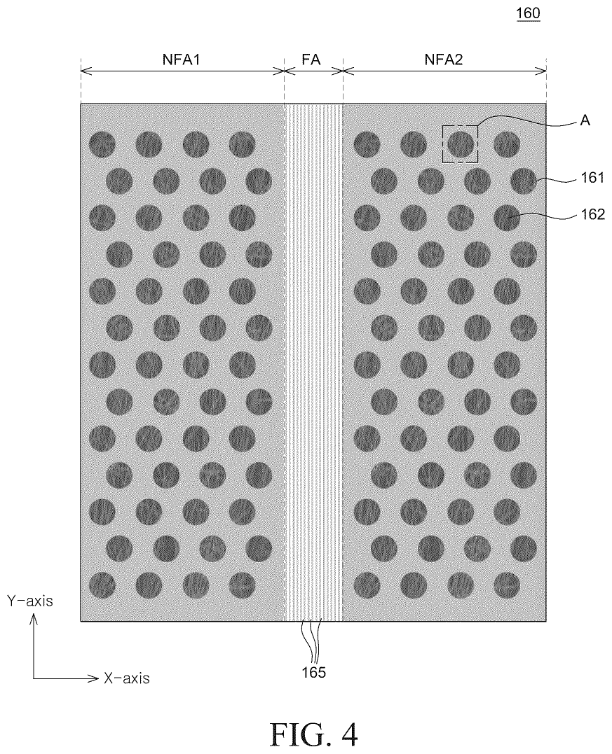

FIG. 4 is a plan view illustrating a structure of a supporting substrate of a display apparatus according to the first exemplary embodiment of the present disclosure.

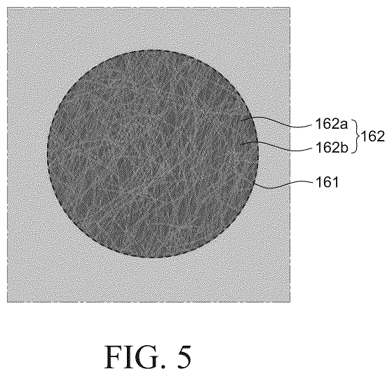

FIG. 5 is a view enlarging a part A of FIG. 4 according to the first exemplary embodiment of the present disclosure.

Referring to FIGS. 2 to 5, the display apparatus 1000 according to the first exemplary embodiment of the present disclosure can include a display panel 100 which displays images and a supporting structure 170 disposed below the display panel 100.

Referring to FIG. 3, the display panel 100 of the first exemplary embodiment of the present disclosure can include a flexible substrate 111 and a display panel component 105 disposed above the substrate 111.

For example, in the display apparatus 1000 according to the first exemplary embodiment of the present disclosure, the display panel 100 can include a flexible substrate 111 with a very thin thickness to implement flexible and foldable properties.

The substrate 111 can be formed of an insulating material having a flexibility, for example, can be one insulating plastic substrate among polyimide, polyethersulfone, polyethylene terephthalate, and polycarbonate, but exemplary embodiments of the present disclosure are not limited thereto.

The buffer layer 113 can be disposed on the substrate 111.

The buffer layer 113 can improve adhesiveness between layers formed above the buffer layer 113 and the substrate 111, and block or prevent alkali components leaked from a lower portion of the buffer layer 113.

The buffer layer 113 can be formed of a single layer of silicone nitride (SiNx) or silicone oxide (SiOx) or a plurality of layers of silicone nitride (SiNx) and silicone oxide (SiOx), but exemplary embodiments of the present disclosure are not limited thereto. However, the buffer layer 113 can be omitted based on a type or a material of the substrate 111 and a structure of the thin film transistor 140, and a type of the thin film transistor 140.

A plurality of barrier metal layers 130 can be disposed on the buffer layer 113.

The plurality of barrier metal layers 130 can protect the active layer 141 of the thin film transistor 140. Each of the plurality of barrier metal layers 130 can be disposed so as to overlap active layers 141 of the plurality of thin film transistors 140 on the buffer layer 113. A width of each of the plurality of barrier metal layers 130 can be equal to or larger than a width of the active layer 141 of each of the plurality of thin film transistors 140. The plurality of barrier metal layers 130 can be formed of various metal materials, and can be in a floating state in which no voltage is applied, but can also be applied with a constant voltage.

An active buffer layer 114 can be disposed above the plurality of barrier metal layers 130 and the buffer layer 113.

The active buffer layer 114 can insulate between the plurality of barrier metal layers 130 and the active layer 141 of the thin film transistor 140. The active buffer layer 114 can be formed of a same material as the buffer layer 113, and for example, can be formed of a single layer of silicone nitride (SiNx) or silicone oxide (SiOx) or a plurality of layers of silicone nitride (SiNx) and silicone oxide (SiOx), but exemplary embodiments of the present disclosure are not limited thereto.

The thin film transistor 140 can be disposed above the active buffer layer 114. For example, the thin film transistor 140 illustrated in FIG. 3 can have a top gate type coplanar structure, but embodiments of the present disclosure are not limited thereto.

For example, the active layer 141 can be disposed on the active buffer layer 114.

The active layer 141 can be formed of a low temperature poly-silicone (LTPS) or an oxide semiconductor, but embodiments of the present disclosure are not limited thereto.

The active layer 141 can include a channel region 141a in which a channel is formed, a source region 141c connected to the source electrode 142, and a drain region 141b connected to the drain electrode 143.

A gate insulating layer 115 can be disposed on the active layer 141.

The gate insulating layer 115 can be configured by a single layer of silicone nitride (SiNx) or silicone oxide (SiOx) or plurality of layers of silicone nitride (SiNx) or silicone oxide (SiOx), but exemplary embodiments of the present disclosure are not limited thereto.

In the gate insulating layer 115, a contact hole through which the source electrode 142 and the drain electrode 143 of the thin film transistor 140 are connected to the source region 141c and the drain region 141b of the active layer 141, respectively, can be formed.

A gate electrode 144 can be disposed on the gate insulating layer 115.

The gate electrode 144 can be formed of various conductive materials, for example, nickel (Ni), chrome (Cr), magnesium (Mg), aluminum (Al), molybdenum (Mo), tungsten (W), and gold (Au), or an alloy thereof, but exemplary embodiments of the present disclosure are not limited thereto. The gate electrode 144 can be disposed on the gate insulating layer 115 so as to overlap the channel region 141a of the active layer 141 of the thin film transistor 140.

An interlayer insulating layer 116 can be disposed above the gate electrode 144 and the gate insulating layer 115.

The interlayer insulating layer 116 can be configured by a single layer of silicone nitride (SiNx) or silicone oxide (SiOx) or a plurality of layers of silicon nitride (SiNx) or silicone oxide (SiOx), but exemplary embodiments of the present disclosure are not limited thereto.

The source electrode 142 and the drain electrode 143 of the thin film transistor 140 can be disposed on the interlayer insulating layer 116. The source electrode 142 and the drain electrode 143 can be electrically connected to the source region 141b and the drain region 141c of the active layer 141, respectively, through contact holes formed in the gate insulating layer 115 and the interlayer insulating layer 116.

The source electrode 142 and the drain electrode 143 can be formed of various conductive materials, for example, nickel (Ni), chrome (Cr), magnesium (Mg), aluminum (Al), molybdenum (Mo), tungsten (W), and gold (Au), or an alloy thereof, but exemplary embodiments of the present disclosure are not limited thereto.

The source electrode 142 and the drain electrode 143 can be formed of a same material through a same process, but embodiments of the present disclosure are not limited thereto.

A planarization layer 117 can be disposed on the interlayer insulating layer 116 on which the source electrode 142 and the drain electrode 143 are disposed. The planarization layer 117 can planarize an upper portion of the thin film transistor 140. As illustrated in FIG. 3, the planarization layer 117 can be a single layer, but can also be formed as a plurality of layers. The planarization layer 117 can be formed of an acrylic organic material, but embodiments of the present disclosure are not limited thereto. The planarization layer 117 can include a contact hole through which the drain electrode 143 of the thin film transistor 140 is electrically connected to the anode 151.

Further, a passivation layer can be further disposed between the thin film transistor 140 and the planarization layer 117. For example, the passivation layer which covers the thin film transistor 140 can be disposed so as to protect the thin film transistor 140 from the permeation of moisture and oxygen. The passivation layer can be formed of an inorganic material and configured by a single layer or a plurality of layers, but embodiments of the present disclosure are not limited thereto.

A light emitting device 150 can be disposed above the planarization layer 117. The light emitting device 150 can include an anode 151 electrically connected to the drain electrode 143 of the thin film transistor 140, an emission layer 152 disposed on the anode 151, and a cathode 153 disposed on the emission layer 152. When the display apparatus 1000 is a top emission type light emitting display apparatus, the anode 151 can further include a reflective layer which reflects the emitted light to the cathode 153 and a transparent conductive layer which supplies holes to the emission layer 152.

A bank 118 can be disposed on the anode 151 and the planarization layer 117.

The bank 118 divides adjacent pixels in the display area to define a plurality of pixels. The bank 118 can be formed of an organic material, but embodiments of the present disclosure are not limited thereto.

An encapsulation layer 155 can be disposed on the cathode 153.

The encapsulation layer 155 can minimize degradation of the components of the display apparatus 100 due to moisture or oxygen. The encapsulation layer 155 can planarize an upper surface of the light emitting device 150. The encapsulation layer 155 can be formed with a multi-layered structure in which an inorganic film and an organic film are laminated. For example, the encapsulation layer 155 can be configured by at least one organic film and at least two inorganic films and have a multilayered structure in which the inorganic film and the organic film are alternately laminated, but exemplary embodiments of the present disclosure are not limited thereto. According to the characteristic of the material, the inorganic film has a barrier characteristic against the moisture and oxygen superior to the organic film. Therefore, the organic film can be disposed between the inorganic films, but embodiments of the present disclosure are not limited thereto. For example, the encapsulation layer 155 can have a triple layered structure including a first inorganic film 156, an organic film 157, and a second inorganic film 158, but exemplary embodiments of the present disclosure are not limited thereto. For example, each of the first inorganic film 156 and the second inorganic film 158 can be formed of one or more of silicone nitride (SiNx), silicone oxide (SiOx), silicone oxynitride (SiON), and aluminum oxide (Al₂O₃), but embodiments of the present disclosure are not limited thereto. For example, the organic film 157 can be formed of one or more of epoxy resin, polyimide, polyethylene, and silicone oxycarbide (SiOC), but embodiments of the present disclosure are not limited thereto.

Referring to FIG. 2, the supporting structure 170 can be disposed below the display panel 100.

The supporting structure 170 can be a plate shaped frame which protects and supports the display panel 100. For example, the supporting structure 170 supports the substrate 111 which configures the display panel 100 so as not to be sagged, and can protect components disposed above the substrate 111 from moisture, heat, and impact from the outside. The supporting structure 170 can be fixed to the display panel 100 by an adhesive material.

The supporting structure 170 can include a supporting substrate 160, a first plate 171, a second plate 172, a first adhesive layer 173, a second adhesive layer 174, and a third adhesive layer 175, but exemplary embodiments of the present disclosure are not limited thereto.

The first plate 171 and the second plate 172 improve the rigidity of the supporting structure 170 and support the display panel 100 together with the supporting substrate 160, but any one of them may not be provided. When the display apparatus 1000 is folded, the first plate 171 and the second plate 172 maintain the curvature of the display panel 100 to be constant, and can suppress or prevent the crease generated on the top surface of the display panel 100. The first plate 171 can be a back plate and the second plate 172 can be a top plate, but embodiments of the present disclosure are not limited thereto.

The first plate 171 and the second plate 172 are disposed between the supporting substrate 160 and the display panel 100, and can be configured by a transparent organic material, but embodiments of the present disclosure are not limited thereto.

A first adhesive layer 173 is disposed between the display panel 100 and the first plate 171, and a second adhesive layer 174 is disposed between the first plate 171 and the second plate 172, and a third adhesive layer 175 can be disposed between the supporting substrate 160 and the second plate 172.

The first adhesive layer 173 is uniformly disposed on an entire upper surface (or an entire top surface) of the first plate 171 to attach the display panel 100 and the first plate 171. The second adhesive layer 174 is uniformly disposed on an entire upper surface (or an entire top surface) of the second plate 172 to attach the first plate 171 and the second plate 172. Further, the third adhesive layer 175 is uniformly disposed on an entire upper surface (or an entire top surface) of the supporting substrate 160 to attach the supporting substrate 160 and the second plate 172.

For example, the first adhesive layer 173, the second adhesive layer 174, and the third adhesive layer 175 can be formed of a transparent adhesive layer, such as optically cleared resin (OCR) or optically cleared adhesive (OCA), but embodiments of the present disclosure are not limited thereto.

A polarization film 180 can be disposed above the display panel 100.

The polarization film 180 can polarize light emitted from the display panel 100 at a polarization angle. The polarization film 180 can emit light which is polarized at a polarization angle to the outside. The polarization film 180 can include a function of blocking reflection of light excluding light which is polarized at a polarization angle, among external light.

A fourth adhesive layer 176 can be disposed between the display panel 100 and the polarization film 180. The fourth adhesive layer 176 is uniformly disposed on an entire upper surface (or an entire top surface) of the display panel 100 to attach the display panel 100 and the polarization film 180. For example, the fourth adhesive layer 176 can be formed of a transparent adhesive layer such as an optically cleared resin (OCR) or an optically cleared adhesive (OCA), but embodiments of the present disclosure are not limited thereto.

The touch panel 185 can be disposed above the polarization film 180. However, embodiments of the present disclosure are not limited thereto and the polarization film 180 can be disposed above the touch panel 185.

The touch panel 185 can directly input information onto the screen by pressing a display screen using a hand or a pen, by a user. For example, the touch panel 185 can be evaluated as the most ideal input method under a graphical user interface (GUI) environment because a user can directly perform a desired operation while looking at the screen and any one can easily operate it. Currently, the touch panel 185 is widely used in various fields, such as mobile phones, PDAs, banks, government offices, various medical equipment, guidance of tourism and major institutions.

A fifth adhesive layer 177 can be disposed between the polarization film 180 and the touch panel 185. The fifth adhesive layer 177 is uniformly disposed on an entire upper surface (or an entire top surface) of the polarization film 180 to attach the polarization film 180 and the touch panel 185. For example, the fifth adhesive layer 177 can be formed of a transparent adhesive layer such as an optically cleared resin (OCR) or an optically cleared adhesive (OCA), but embodiments of the present disclosure are not limited thereto.

A cover window 190 can be disposed above the touch panel 185.

The cover window 190 can protect the display panel 100 from the external impact. The cover window 190 can be implemented by a soft plastic based cover which is foldable, to ensure the thin thickness and the flexibility of the display apparatus 1000.

A sixth adhesive layer 178 can be disposed between the touch panel 185 and the cover window 190. The sixth adhesive layer 178 is uniformly disposed on an entire upper surface (or an entire top surface) of the touch panel 185 to attach the touch panel 185 and the cover window 190. For example, the sixth adhesive layer 178 can be formed of a transparent adhesive layer, for example, an optically cleared resin (OCR) or an optically cleared adhesive (OCA), but embodiments of the present disclosure are not limited thereto.

FIG. 2 illustrates an example in which the touch panel 185 is disposed above the polarization film 180, but embodiments of the present disclosure are not limited thereto. As described above, the polarization film 180 can be disposed above the touch panel 185. In this case, the fourth adhesive layer 176 can be disposed between the display panel 100 and the touch panel 185 and the fifth adhesive layer 177 can be disposed between the touch panel 185 and the polarization film 180, and the sixth adhesive layer 178 can be disposed between the polarization film 180 and the cover window 190.

Referring to FIGS. 2, 4, and 5, the display apparatus 1000 according to the first exemplary embodiment of the present disclosure can include the supporting substrate 160 disposed below the display panel 100.

The supporting substrate 160 can include a plurality of opening patterns 165 corresponding to the folding area FA. The opening pattern 165 allows the supporting substrate 160 of the folding area to be easily folded and easily restored to its original state after being folded to improve the folding performance of the display apparatus 1000.

The opening pattern 165 formed in the folding area FA of the supporting substrate 160 can be formed to have an oval shape having a major axis in the Y-axis direction and having a constant length of a minor axis. For example, the opening pattern 165 can have a shape in which a semi-circle is coupled to both ends of a rectangle. Further, the opening patterns 165 can be disposed to be spaced apart from each other with a predetermined distance.

The supporting substrate 160 can support the display panel 100 so that the supporting substrate can be referred to as a bottom plate or a plate.

The supporting substrate 160 can be formed of metal material. The metal material may include at least one of iron (Fe), aluminum (Al), magnesium (Mg), a stainless steel (SUS), and a stainless steel (SUS) including nickel (Ni), but exemplary embodiments of the present disclosure are not limited thereto. The stainless steel has a high restoring force and rigidity so that even though the thickness of the supporting substrate 160 is reduced, the supporting structure 170 can maintain a desired rigidity. Therefore, the supporting structure 170 supports the display panel 100 and reduces an overall thickness of the display apparatus 1000 so that a radius of curvature of the folding area FA can be reduced. However, the supporting substrate 160 is not limited thereto and can be configured by a polymer such as polymethylmetacrylate (PMMA), polycarbonate (PC), polyvinylalcohol (PVA), acrylonitirlebutadiene-styrene (ABS), or polyethylene terephthalate (PET), but exemplary embodiments of the present disclosure are not limited thereto.

For example, a thickness of the supporting substrate 160 can be 20 μm to 1,000 μm, for example, can be 100 μm to 200 μm, but exemplary embodiments of the present disclosure are not limited thereto. In this case, the supporting substrate 160 can be folded while maintaining the rigidity and the supporting performance.

The opening patterns 165 of the supporting substrate 160 can be formed with different shapes or different intervals (or distances) in the folding area FA. For example, the opening pattern 165 can be formed to have rectangular shape, rhombus shape, or circular shape, but exemplary embodiments of the present disclosure are not limited thereto.

According to the first exemplary embodiment of the present disclosure, a plurality of hole patterns 161 can be formed in the non-folding areas NFA1 and NFA2 of the supporting substrate 160.

The hole pattern 161 can be filled with a restoration member 162 which is formed of a polymer 162b in which shape memory materials 162a are dispersed.

According to one or more embodiments of the present disclosure, the plurality of hole patterns 161 is formed in the non-folding areas NFA1 and NFA2 of the supporting substrate 160 to be filled with the polymer 162b in which shape memory materials 162a are dispersed to restore the deformation. Accordingly, the step differences between the adhesive layers 173, 174, 175, 176, 177, and 178 and the supporting substrate 160, for example, between the third adhesive layer 175 and the supporting substrate 160 is minimized to relieve the waviness phenomenon of the supporting substrate 160 of the folding area FA. Further, a waved surface of the supporting substrate 160 of the folding area FA generated due to the bending is minimized to improve the visibility and the durability.

For example, the shape memory material 162a has a property that returns to a state before being deformed when a certain temperature is reached after plastic deformation is applied by the external force. Therefore, the deformation of the third adhesive layer 175 is minimized by the shape memory material 162a dispersed in the hole pattern 161 and the step difference between the supporting substrate 160 and the third adhesive layer 175 can be minimized.

Further, the shape memory material 162a functions to hold the third adhesive layer 175 to minimize the step difference between the supporting substrate 160 and the third adhesive layer 175 to improve the durability of the display apparatus 1000.

Further, as described above, the hole pattern 161 and the restoration member 162 of the present disclosure are formed in the non-folding areas NFA1 and NFA2 of the supporting substrate 160 to minimize the step differences between the adhesive layers 173, 174 175, 176, 177, and 178 and the supporting substrate 160, but embodiments of the present disclosure are not limited thereto. However, the restoration member 162 of the present disclosure is not formed only in the supporting substrate 160. However, the deformation of the adhesive layers 173, 174 175, 176, 177, and 178 due to the external force which folds, rolls, or bends the display apparatus 1000 is significant in the third adhesive layer 175 around the opening pattern 165 formed in the folding area FA of the supporting substrate 160. Therefore, when the restoration member is applied to the supporting substrate 160 which is in contact with the third adhesive layer 175, the effect can be more significant.

For example, the shape memory material 162a can be configured by silver nano wire (Ag NW), but embodiments of the present disclosure not limited thereto.

The polymer 162b can be configured by a similar to or same material as the base material of the adhesive layers 173, 174 175, 176, 177, and 178. For example, the polymer can be configured by acrylic based material or silicone based material, but exemplary embodiments of the present disclosure are not limited thereto.

Even though there can be a difference depending on a level of the shape input at an initial state, the shape memory materials 162a can be dispersed in the polymer 162b with a content of 20% to 35% so as to effectively suppress the deformation of the third adhesive layer 175. The shape memory material 162a is dispersed in the polymer 162b to be embedded so that the shape memory material does not affect the surface adhesiveness and the shape memory material is disposed below the display panel so that it does not affect a transmittance.

If a content of the shape memory material 162a is 10% or less, a polymer network of the shape memory material 162a can be disconnected due to the damage caused by repeated phenomenon (bending) of a plurality of times of contraction and extension. In this case, a phenomenon to be implemented may not be realized anymore.

When the content of the shape memory material 162a is increased to 50% or more, there is a risk of transfer due to the increased roughness of the surface of the polymer 162b and a surface area which implements the adhesiveness can be reduced due to the protrusion of the shape memory material 162a. Therefore, the deformation of the third adhesive layer 175 may not be effectively suppressed.

In the case of the display apparatus 1000 according to the first exemplary embodiment of the present disclosure, when a puncture test was applied, it was confirmed that the puncture was improved from 4 kgf (kilogram/force) to 5 kgf. Further, it can be confirmed that the phenomenon in which the opening pattern 165 of the supporting substrate 160 is visible is improved.

The higher the ratio of an area occupied by the hole pattern 161 to a total area of the non-folding areas NFA1 and NFA2 of the supporting substrate 160, the greater the restoration effect of the third adhesive layer 175. However, the adhesiveness with the display panel 100 is degraded and a degree of supporting the display panel 100 can be degraded.

An adhesiveness effect according to an area ratio occupied by the hole pattern 161 in the total area of the non-folding areas NFA1 and NFA2 will be described. An area ratio occupied by the hole pattern 161 which effectively implements the adhesiveness while maintaining the rigidity of the supporting substrate 160 which supports the display panel 100 can be approximately 65% to 80%.

A shape and a placement of the hole pattern according to some embodiments of the present disclosure are not limited to the circular or uniform placement illustrated in FIGS. 4 and 5, but can have various shapes and placements, which will be described in detail with reference to the drawings.

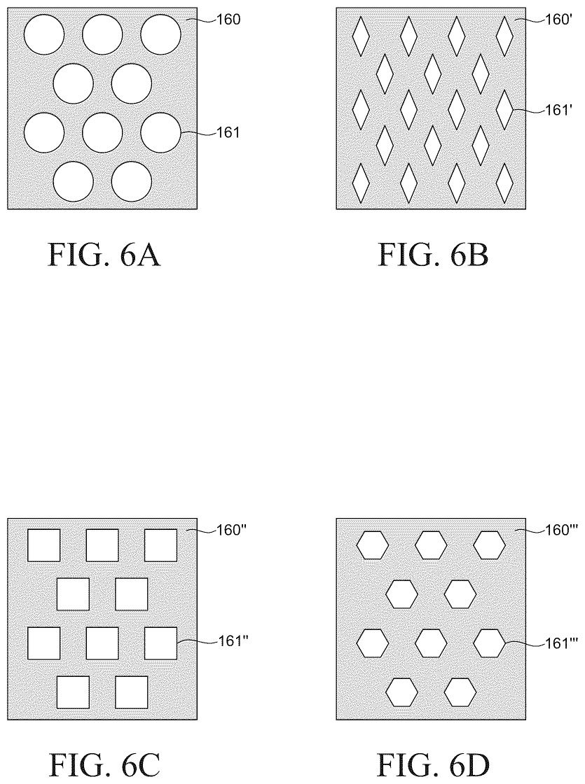

FIGS. 6A to 6D illustrate different examples of a shape of a hole pattern according to an embodiment of the present disclosure.

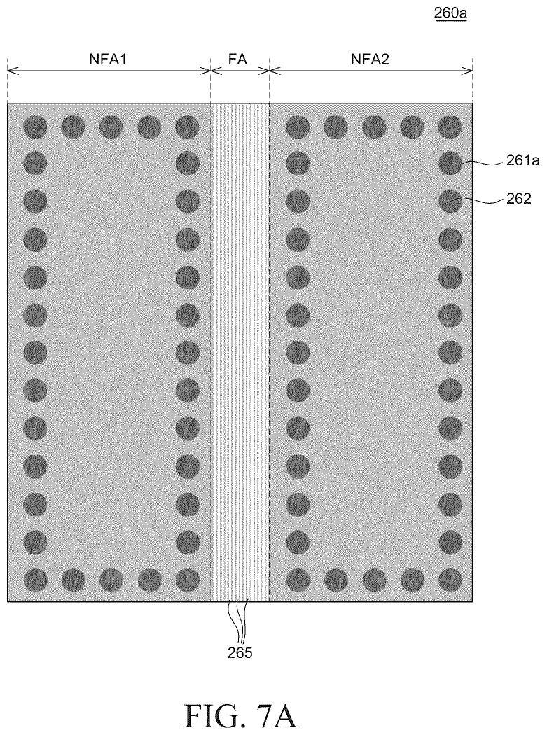

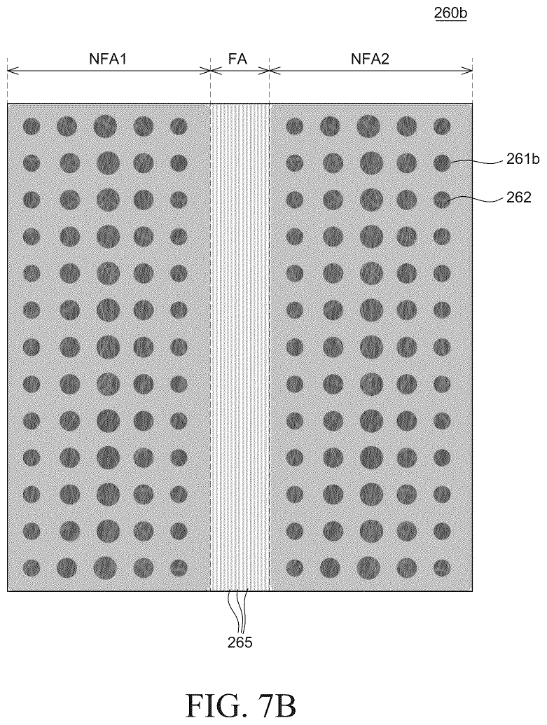

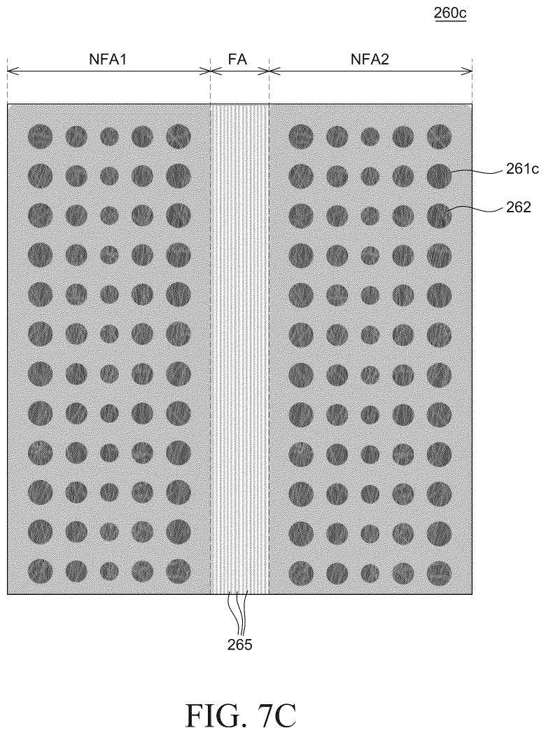

FIGS. 7A to 7C illustrate various examples of a supporting substrate according to a second exemplary embodiment of the present disclosure.

FIGS. 6A to 6D illustrate a part of supporting substrates 160, 160′, 160″ and 160′″ according to the first exemplary embodiment of the present disclosure.

The difference between supporting substrates 260a, 260b, and 260c according to the second exemplary embodiment of the present disclosure of FIGS. 7A to 7C and the supporting substrate 160 of the first exemplary embodiment of FIG. 4 is a placement of the hole patterns 261a, 261b, and 261c. However, the other configurations are substantially the same so that a redundant description can be omitted or briefly provided.

Referring to FIGS. 6A to 6D, the hole patterns 161, 161′, 161″, and 161′″ of the first exemplary embodiment of the present disclosure can have various shapes, such as a rhombus shape of FIG. 6B, a square shape of FIG. 6C, and a hexagon shape of FIG. 6D, in addition to a circle shape of FIG. 6A, but embodiments of the present disclosure are not limited thereto.

The hole patterns 161, 161′, 161″, and 161′″ of the first exemplary embodiment of the present disclosure can be uniformly disposed in the non-folding area of the supporting substrates 160, 160′, 160″, and 160′″, but embodiments of the present disclosure are not limited thereto. Further, the hole patterns 161, 161′, 161″, and 161′″ of the first exemplary embodiment of the present disclosure can have substantially a same size over the entire surface of the supporting substrates 160, 160′, 160″, and 160′″, but embodiments of the present disclosure are not limited thereto.

For example, referring to FIG. 7A, the hole pattern 261a according to a second exemplary embodiment of the present disclosure can be disposed only in the peripheries of the non-folding areas NFA1 and NFA2 of the supporting substrate 260a. In FIG. 7A, an example that the hole pattern 261a is disposed in only peripheries of four surfaces of the non-folding areas NFA1 and NFA2 is illustrated, but embodiments of the present disclosure are not limited thereto. For example, the hole pattern can be disposed only in inner peripheries of the non-folding areas NFA1 and NFA2 adjacent to the folding area FA, and can be disposed only in a middle portion of the non-folding areas NFA1 and NFA2.

Further, referring to FIG. 7B, the hole pattern 261b of the second exemplary embodiment of the present disclosure can be disposed such that sizes of the hole patterns 261b are decreased toward the left portions and the right portions from the middle portion with respect to each of the non-folding areas NFA1 and NFA2 of the supporting substrate 260b. However, embodiments of the present disclosure are not limited thereto and the hole pattern 261b can be disposed such that the sizes of the hole pattern 261b are decreased from the middle portion to the peripheries of four-side with respect to each of the non-folding areas NFA1 and NFA2 of the supporting substrate 260b.

Further, referring to FIG. 7C, the hole pattern 261c of the second exemplary embodiment of the present disclosure can be disposed such that sizes of the hole patterns 261c are increased toward the left portions and the right portions from the middle portion with respect to each of the non-folding areas NFA1 and NFA2 of the supporting substrate 260c. However, embodiments of the present disclosure are not limited thereto and the hole pattern 261c can be disposed such that the sizes of the hole patterns 261c are increased from the middle portions to the peripheries of four-side with respect to each of the non-folding areas NFA1 and NFA2 of the supporting substrate 260c.

Referring to FIGS. 7A to 7C, as described above, a plurality of hole patterns 261a, 261b, and 261c can be formed at the non-folding areas NFA1 and NFA2 of the supporting substrates 260a, 260b, and 260c.

A restoration member 262 which is formed by a polymer in which shape memory materials are dispersed can be filled in the hole patterns 261a, 261b, and 261c.

For example, the shape memory material can be configured by silver nano wire (Ag NW), but embodiments of the present disclosure are not limited thereto.

The polymer can be configured by a similar or same material as the base material of the adhesive layer. For example, the polymer can be configured by acrylic based material or silicone based material, but exemplary embodiments of the present disclosure are not limited thereto.

The supporting substrates 260a, 260b, and 260c can include a plurality of opening patterns 265 corresponding to the folding area FA.

The opening patterns 265 of the supporting substrates 260a, 260b, and 260c can be formed with different shapes or different intervals (or distances) in the folding area FA, but embodiments of the present disclosure are not limited thereto. For example, the opening pattern 265 can be formed to have rectangular shape, rhombus shape, or circular shape, but exemplary embodiments of the present disclosure are not limited thereto.

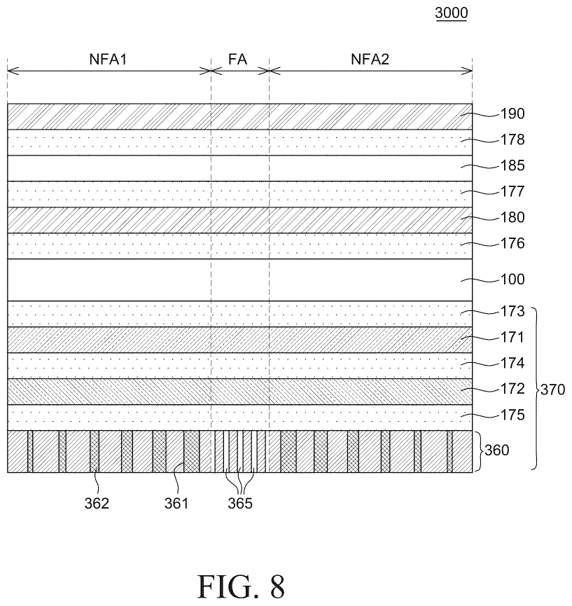

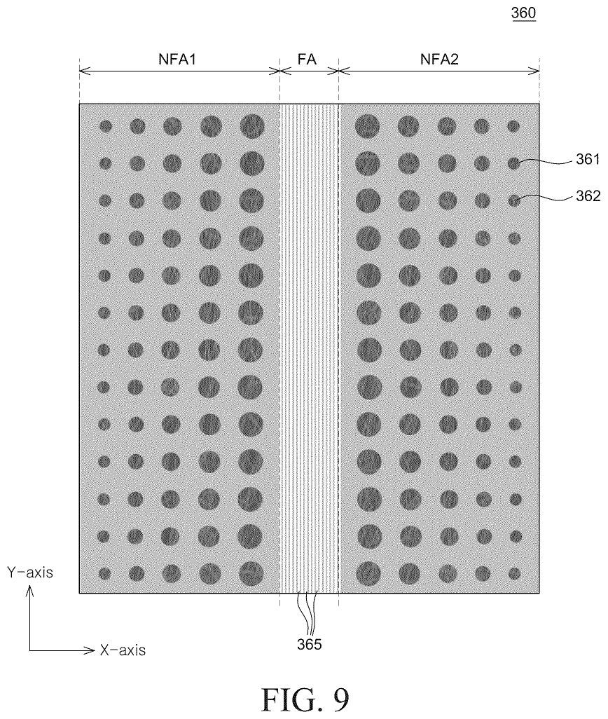

The shape and the placement of the hole patterns are not limited as described above, and as described above, a deformation of the adhesive layer due to the external force can be significant around the opening pattern formed in the folding area of the supporting substrate. A size of the hole pattern can be largest at the inner periphery of the non-folding area adjacent to the folding area and the size of the hole pattern can be gradually decreased from the inner periphery to the outer periphery, which will be described in more detail with reference to FIGS. 8 and 9.

FIG. 8 illustrate a cross-sectional structure of a display apparatus according to a third exemplary embodiment of the present disclosure.

FIG. 9 is a plan view illustrating a structure of a supporting substrate of a display apparatus according to the third exemplary embodiment of the present disclosure.

The difference of a display apparatus 3000 of the third exemplary embodiment of the present disclosure of FIGS. 8 and 9 and the above-described display apparatus 1000 of the first exemplary embodiment of FIGS. 2 to 4 is a size of a hole pattern 360, but the other configurations are substantially the same. Therefore, a redundant description can be omitted or briefly provided.

Referring to FIGS. 8 and 9, the display apparatus 3000 according to the third exemplary embodiment of the present disclosure can include a display panel 100 and a supporting structure 370 disposed below the display panel 100.

The supporting structure 370 can include a supporting substrate 360, a first plate 171, a second plate 172, a first adhesive layer 173, a second adhesive layer 174, and a third adhesive layer 175, but exemplary embodiments of the present disclosure are not limited thereto.

The first plate 171 and the second plate 172 improve the rigidity of the supporting structure 370 and support the display panel 100 together with the supporting substrate 360, but any one of them may not be provided.

The first plate 171 and the second plate 172 are disposed between the supporting substrate 360 and the display panel 100, and can be configured by a transparent organic material, but embodiments of the present disclosure are not limited thereto.

The first adhesive layer 173 is disposed between the display panel 100 and the first plate 171, the second adhesive layer 174 is disposed between the first plate 171 and the second plate 172, and a third adhesive layer 175 can be disposed between the supporting substrate 360 and the second plate 172.

A polarization film 180 can be disposed above the display panel 100.

A fourth adhesive layer 176 can be disposed between the display panel 100 and the polarization film 180.

The touch panel 185 can be disposed above the polarization film 180.

A fifth adhesive layer 177 can be disposed between the polarization film 180 and the touch panel 185.

A cover window 190 can be disposed above the touch panel 185.

A sixth adhesive layer 178 can be disposed between the touch panel 185 and the cover window 190.

The supporting substrate 360 can include a plurality of opening patterns 365 corresponding to the folding area FA.

The opening pattern 365 formed in the folding area FA of the supporting substrate 360 can be formed to have an oval shape having a major axis in the Y-axis direction and having a constant length of a minor axis. For example, the opening pattern 365 can have a shape in which a semi-circle is coupled to both ends of a rectangle. Further, each opening patterns 365 can be disposed to be spaced apart from each other with a predetermined interval (or distance).

The opening patterns 365 of the supporting substrate 360 can be formed with different shapes or different intervals (distances) in the folding area FA. For example, the opening pattern 365 can be formed to have rectangular shape, rhombus shape, or circular shape, but exemplary embodiments of the present disclosure are not limited thereto.

According to the third exemplary embodiment of the present disclosure, to be the same as the above-described first and second exemplary embodiments, a plurality of hole patterns 361 can be formed in the non-folding areas NFA1 and NFA2 of the supporting substrate 360.

A restoration member 362 which is formed by a polymer in which shape memory materials are dispersed can be filled in the hole pattern 361.

For example, the shape memory material can be configured by silver nano wire (Ag NW), but embodiments of the present disclosure are not limited thereto.

The polymer can be configured by a similar to or same material as the base material of the adhesive layers 173, 174 175, 176, 177, and 178. For example, the polymer can be configured by acrylic based material or silicone based material, but exemplary embodiments of the present disclosure are not limited thereto.

Therefore, the waviness phenomenon of the supporting substrate 360 of the folding area FA can be relieved by minimizing the step difference between the third adhesive layer 175 and the supporting substrate 360. Further, a waved surface of the supporting substrate 360 of the folding area FA generated due to the bending is minimized to improve the visibility and the durability.

Further, the shape memory material functions to hold the third adhesive layer 175 to minimize the step difference between the supporting substrate 360 and the third adhesive layer 175 to improve the durability of the display apparatus 3000.

According to the third exemplary embodiment of the present disclosure, the deformation of the third adhesive layer 175 by the external force can be more remarkable around the opening pattern 365 formed in the folding area FA of the supporting substrate 360. Therefore, the size of the hole pattern 361 is the largest in the inner periphery of the non-folding areas NFA1 and NFA2 adjacent to the folding area FA, and the size of the hole pattern 361 is configured to be gradually decreased from the inner periphery to the outer periphery.

According to the third exemplary embodiment of the present disclosure, a hole pattern 361 having a relatively large size is disposed at the inner periphery of the non-folding areas NFA1 and NFA2 adjacent to the folding area FA in which deformation such as lifting frequently occurs to effectively suppress or prevent the deformation.

As described above, there can be a difference depending on a level of the shape input at the initial stage and the shape memory materials can be dispersed in the polymer with a content of 20% to 35% so as to effectively suppress or prevent the deformation of the third adhesive layer 175.

The higher the ratio of an area occupied by the hole pattern 360 to a total area of the non-folding areas NFA1 and NFA2 of the supporting substrate 360, the greater the restoration effect of the third adhesive layer 175. However, the adhesiveness with the display panel 100 is degraded and a degree of supporting the display panel 100 can be degraded.

An adhesiveness effect according to an area ratio occupied by the hole pattern 361 in the total area of the non-folding areas NFA1 and NFA2 will be described. An area ratio occupied by the hole pattern 361 which effectively implements the adhesiveness while maintaining the rigidity of the supporting substrate 360 which supports the display panel 100 can be approximately 65% to 80%.

Here, the area ratio is a percentage value obtained by dividing a total area of the hole pattern 361 by a total area of the non-folding areas NFA1 and NFA2 of the supporting substrate 360 without having the hole pattern 361. When a level of the adhesiveness with respect to the most effective area of the hole pattern 361 is defined as 1, the level of the adhesiveness can be 1 at an area ratio of approximately 65% to 80%.

If the area ratio is less than 50%, the level of adhesiveness is 0.5 and if the area ratio is 50% to 65%, the level of adhesiveness is 0.8. When the area ratio exceeds 80%, a polymer area is larger than the rigid area so that it is difficult to function as a supporting substrate which supports the entire display apparatus.

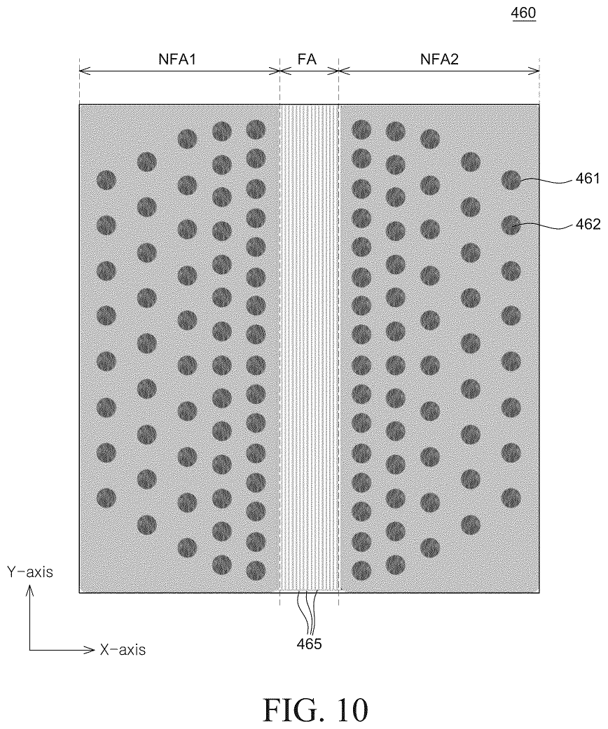

FIG. 10 is a plan view illustrating a structure of a supporting substrate of a display apparatus according to a fourth exemplary embodiment of the present disclosure.

The difference of a display apparatus of the fourth exemplary embodiment of the present disclosure and the display apparatus 1000 of the first exemplary embodiment of FIGS. 2 and 4 is a placement density of the hole pattern 461, but the other configurations are substantially the same so that a redundant description can be omitted or briefly provided.

Similar to the above-described first, second and third exemplary embodiments of the present disclosure, the display apparatus according to the fourth exemplary embodiment of the present disclosure can include a supporting structure disposed below the display panel.

Referring to FIG. 10, the supporting structure can include a supporting substrate 460 and the supporting substrate 460 can include a plurality of opening patterns 465 corresponding to the folding area FA.

According to the fourth exemplary embodiment of the present disclosure, to be the same as the above-described first, second, and third exemplary embodiments of the present disclosure, a plurality of hole patterns 461 can be formed in the non-folding areas NFA1 and NFA2 of the supporting substrate 460.

According to the fourth exemplary embodiment of the present disclosure, to effectively suppress the deformation of the third adhesive layer by the external force, a placement density of the hole pattern 461 is the highest in the inner periphery of the non-folding areas NFA1 and NFA2 adjacent to the folding area FA. The placement density of the hole patterns 461 can be configured to be gradually reduced from the inner periphery to the outer periphery.

According to the fourth exemplary embodiment of the present disclosure, the placement density of the hole patterns 461 are adjusted to be relatively high in the inner periphery of the non-folding areas NFA1 and NFA2 adjacent to the folding area FA. Thus, the deformation of the third adhesive layer due to the external force can be effectively suppressed or prevented. Further, a restoration member 462 which is formed by a polymer in which shape memory materials are dispersed can be filled in the hole pattern 461.

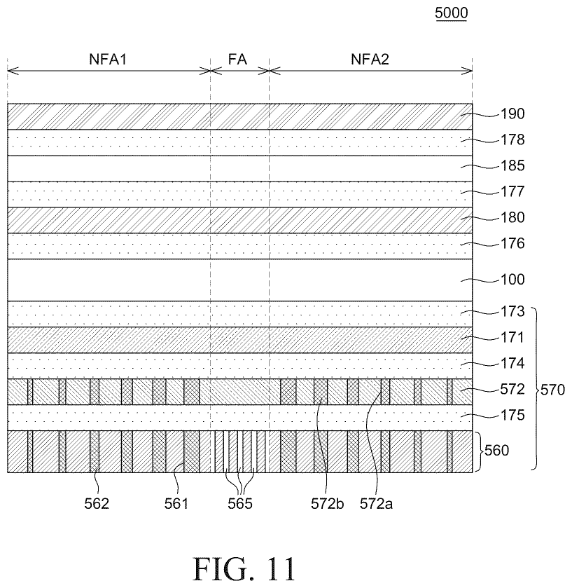

FIG. 11 illustrates a cross-sectional structure of a display apparatus according to a fifth exemplary embodiment of the present disclosure.

The difference of a display apparatus 5000 of the fifth exemplary embodiment of the present disclosure and the above-described display apparatus 3000 according to the third exemplary embodiment of the present disclosure of FIGS. 8 and 9 is a configuration of the second plate 572, but the other configurations are substantially the same. Therefore, a redundant description can be omitted or briefly provided.

Referring to FIG. 11, the display apparatus 5000 according to the fifth exemplary embodiment of the present disclosure can include a display panel 100 and a supporting structure 570 disposed below the display panel 100.

The supporting structure 570 can include a supporting substrate 560, a first plate 171, a second plate 572, a first adhesive layer 173, a second adhesive layer 174, and a third adhesive layer 175.

The first adhesive layer 173 can be disposed between the display panel 100 and the first plate 171. The second adhesive layer 174 can be disposed between the first plate 171 and the second plate 572. The third adhesive layer 175 can be disposed between the supporting substrate 560 and the second plate 572.

The supporting substrate 560 can include a plurality of opening patterns 565 corresponding to the folding area FA.

According to the fifth exemplary embodiment of the present disclosure, to be the same as the above-described first, second, third, and fourth exemplary embodiments of the present disclosure, a plurality of hole patterns 561 can be formed in the non-folding areas NFA1 and NFA2 of the supporting substrate 560.

A restoration member 562 which is formed by a polymer in which shape memory materials are dispersed can be filled in the hole pattern 561.

According to the fifth exemplary embodiment of the present disclosure, to effectively suppress or prevent the deformation of the third adhesive layer 175 by the external force, the hole pattern 561 has the largest size in the inner periphery of the non-folding areas NFA1 and NFA2 adjacent to the folding area FA. The size of the hole patterns 561 can be configured to be gradually decreased from the inner periphery to the outer periphery.

Further, according to the fifth exemplary embodiment of the present disclosure, a plurality of hole patterns 572a can be formed not only on the supporting substrate 560, but also in the non-folding areas NFA1 and NFA2 of the second plate 572 above the third adhesive layer 175.

A restoration member 572b which is formed by a polymer in which shape memory materials are dispersed can be filled in the hole pattern 572a.

For example, the shape memory material can be configured by silver nano wire (Ag NW), but embodiments of the present disclosure are not limited thereto. The polymer can be configured by a similar or same material as the base material of the third adhesive layer 175. For example, the polymer can be configured by acrylic based material or silicone based material, but exemplary embodiments of the present disclosure are not limited thereto.

According to the fifth exemplary embodiment of the present disclosure, the hole pattern 572a has the largest size in the inner periphery of the non-folding areas NFA1 and NFA2 of the second plate 572, and the size of the hole pattern 572a can be configured to be gradually decreased from the inner periphery to the outer periphery. However, embodiments of the present disclosure are not limited thereto, and as described above, the hole pattern 572a can be disposed to have the same size in the non-folding areas NFA1 and NFA2. Further, the hole pattern can be uniformly disposed in the non-folding areas NFA1 and NFA2 or disposed only in the periphery, or only in the inner periphery, or only in the middle portion. Further, the hole patterns 572a can be disposed such that the size is gradually decreased from the middle portion to the left portion and the right portion with respect to each of the non-folding areas NFA1 and NFA2, or can be disposed such that the size is decreased from the middle portion to the four-side peripheries with respect to each of the non-folding areas NFA1 and NFA2.

According to the fifth exemplary embodiment of the present disclosure, a hole pattern 572a having a relatively large size is disposed not only in the non-folding areas NFA1 and NFA2 adjacent to the folding area FA of the supporting substrate 560 in which deformation such as lifting frequently occurs, but also in the inner periphery of the non-folding areas NFA1 and NFA2 of the second plate 572. Thus, the deformation can be more effectively suppressed or prevented.

However, embodiments of the present disclosure are not limited thereto so that it can be applied to the first plate 171, as well as the second plate 572.

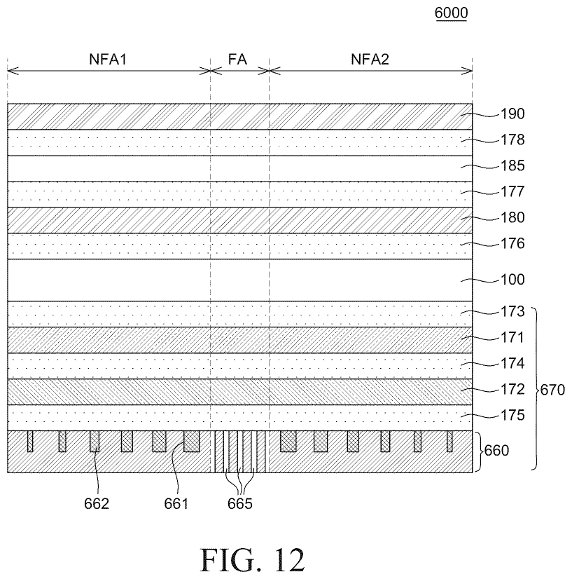

FIG. 12 illustrates a cross-sectional structure of a display apparatus according to a sixth exemplary embodiment of the present disclosure.

The difference of a display apparatus 6000 of the sixth exemplary embodiment of the present disclosure and the display apparatus 3000 according to the third exemplary embodiment of FIGS. 8 and 9 described above is a configuration of the groove pattern 661, but the other configurations are substantially the same. Therefore, a redundant description can be omitted or briefly provided.

Referring to FIG. 12, the display apparatus 6000 according to the sixth exemplary embodiment of the present disclosure can include a display panel 100 and a supporting structure 670 disposed below the display panel 100.

The supporting structure 670 can include a supporting substrate 660, a first plate 171, a second plate 172, a first adhesive layer 173, a second adhesive layer 174, and a third adhesive layer 175.

The supporting substrate 660 can include a plurality of opening patterns 665 corresponding to the folding area FA.

According to the sixth exemplary embodiment of the present disclosure, unlike the above-described first, second, third, fourth, and fifth exemplary embodiments of the present disclosure, a plurality of groove patterns 661, instead of the hole patterns, can be formed in the non-folding areas NFA1 and NFA2 of the supporting substrate 660. The groove pattern 661 can be formed in the non-folding areas NFA1 and NFA2 on the upper surface (or top surface) of the supporting substrate 660 which is in contact with the third adhesive layer 175. The groove pattern 661 can be formed to have a predetermined depth from the upper portion (or top portion) to the lower portion (or bottom portion) of the supporting substrate 660.

A restoration member 662 which is formed by a polymer in which shape memory materials are dispersed can be filled in the groove pattern 661.

For example, the shape memory material can be configured by silver nano wire (Ag NW), but embodiments of the present disclosure are not limited thereto. The polymer can be configured by a similar or same material as the base material of the third adhesive layer 175. For example, the polymer can be configured by acrylic based material or silicone based material, but exemplary embodiments of the present disclosure are not limited thereto.

According to the sixth exemplary embodiment of the present disclosure, to effectively suppress or prevent the deformation of the third adhesive layer 175 by the external force, the groove pattern 661 has the largest size in the inner periphery of the non-folding areas NFA1 and NFA2 adjacent to the folding area FA. The size of the groove patterns 661 can be configured to be gradually decreased from the inner periphery to the outer periphery. However, embodiments of the present disclosure are not limited thereto, and as described above, the groove pattern 661 can be disposed to have the same size in the non-folding areas NFA1 and NFA2. Further, the hole pattern can be uniformly disposed in the non-folding areas NFA1 and NFA2 or disposed only in the periphery, or only in the inner periphery, or only in the middle portion. Further, the groove pattern 661 can be disposed such that the size is gradually decreased from the middle portion to the left portion and the right portion with respect to each of the non-folding areas NFA1 and NFA2, or can be disposed such that the size is decreased from the middle portion to the four-side peripheries with respect to each of the non-folding areas NFA1 and NFA2.

A display apparatus according to one or more embodiments of the present disclosure are described below.

A display apparatus according to one or more embodiments of a present disclosure may comprise a display panel including a folding area and a non-folding area adjacent to the folding area and a supporting substrate disposed below the display panel, the supporting substrate including a plurality of opening patterns corresponding to the folding area, and a plurality of hole patterns or a plurality of groove patterns corresponding to the non-folding area.

According to one or more embodiments of the present disclosure, the display apparatus can further include a first plate disposed below the display panel and a first adhesive layer disposed between the display panel and the first plate.

According to one or more embodiments of the present disclosure, the display apparatus can further include a second plate disposed below the first plate and a second adhesive layer disposed between the first plate and the second plate.

According to one or more embodiments of the present disclosure, the display apparatus can further include a third adhesive layer disposed between the second plate and the supporting substrate.

According to one or more embodiments of the present disclosure, the first, the second, and the third adhesive layers can include a transparent adhesive layer, and the transparent adhesive layer can include an optically cleared resin (OCR) or an optically cleared adhesive (OCA).

According to one or more embodiments of the present disclosure, the display apparatus can further include a polarization film disposed above the display panel, a touch panel disposed above the polarization film, and a cover window disposed above the touch panel.

According to one or more embodiments of the present disclosure, the display apparatus can further include a fourth adhesive layer disposed between the display panel and the polarization film, a fifth adhesive layer disposed between the polarization film and the touch panel and a sixth adhesive layer disposed between the touch panel and the cover window.

According to one or more embodiments of the present disclosure, the display apparatus can further include a touch panel disposed above the display panel, a polarization film disposed above the touch panel and a cover window disposed above the polarization film.

According to one or more embodiments of the present disclosure, the display apparatus can further include a fourth adhesive layer disposed between the display panel and the touch panel, a fifth adhesive layer disposed between the touch panel and the polarization film and a sixth adhesive layer disposed between the polarization film and the cover window.

According to one or more embodiments of the present disclosure, the display apparatus can further include a restoration member disposed in at least one of the plurality of hole patterns or the plurality of groove patterns, the restoration member includes a polymer in which shape memory materials are dispersed.

According to one or more embodiments of the present disclosure, the shape memory materials can be formed of silver nano wire.

According to one or more embodiments of the present disclosure, the polymer can be configured by an acrylic based material or silicone based material.

According to one or more embodiments of the present disclosure, the supporting substrate can include a metal material or a polymer, the metal material can include at least one of iron (Fe), aluminum (Al), magnesium (Mg) a stainless steel, and a stainless steel including nickel (Ni).

According to one or more embodiments of the present disclosure, the shape memory materials can be dispersed in the polymer with a content of 20% to 35%.

According to one or more embodiments of the present disclosure, an area ratio occupied by one of the plurality of hole patterns to an entire area of a corresponding non-folding area among the non-folding areas can be 65% to 80%.

According to one or more embodiments of the present disclosure, each of at least one of the plurality of hole patterns can have a circle shape, a rhombus shape, a square shape, or a hexagonal shape.

According to one or more embodiments of the present disclosure, at least one of the plurality of hole patterns or the plurality of groove patterns can be uniformly disposed in a corresponding non-folding area among the non-folding areas.

According to one or more embodiments of the present disclosure, at least one of the plurality of hole patterns or the plurality of groove patterns can have a same size over the entire surface of the non-folding area among the non-folding areas.

According to one or more embodiments of the present disclosure, at least one of the plurality of hole patterns or the plurality of groove patterns can be disposed only at a periphery of one of the non-folding areas of the supporting substrate.

According to one or more embodiments of the present disclosure, at least one of the plurality of hole patterns or the plurality of groove patterns can be disposed only at an inner periphery of one of the non-folding areas of the supporting substrate.

According to one or more embodiments of the present disclosure, at least one of the plurality of hole patterns or the plurality of groove patterns can be disposed only in a middle portion of one of the non-folding areas of the supporting substrate.

According to one or more embodiments of the present disclosure, a size of at least one of the plurality of hole patterns or the plurality of groove patterns can decrease from a middle portion to a left portion and a right portion with respect to one of the non-folding areas of the supporting substrate.

According to one or more embodiments of the present disclosure, a size of at least one of the plurality of hole patterns or the plurality of groove patterns can decrease from a middle portion to four-side peripheries with respect to one of the non-folding areas of the supporting substrate.

According to one or more embodiments of the present disclosure, a size of at least one of the plurality of the hole patterns or the plurality of groove patterns can increase from a middle portion to a left portion and a right portion with respect to one of the non-folding areas of the supporting substrate.

According to one or more embodiments of the present disclosure, a size of at least one of the plurality of the hole patterns or the plurality of groove patterns can increase from a middle portion to four-side peripheries with respect to one of the non-folding areas of the supporting substrate.

According to one or more embodiments of the present disclosure, a size of at least one of the plurality of the hole patterns or the plurality of groove patterns can be the largest in an inner periphery of one of the non-folding areas adjacent to the folding area of the supporting substrate, and gradually decrease from the inner periphery to an outer periphery.

According to one or more embodiments of the present disclosure, a density of at least one of the plurality of the hole patterns or the plurality of groove patterns can be the largest in an inner periphery of one of the non-folding areas adjacent to the folding area of the supporting substrate, and gradually decrease from the inner periphery toward an outer periphery.

According to one or more embodiments of the present disclosure, the second plate can include a plurality of hole patterns corresponding to one of the non-folding areas.

According to one or more embodiments of the present disclosure, the display apparatus can further include a restoration member disposed in the plurality of hole patterns of the second plate, the restoration member can include polymer in which shape memory materials are dispersed.

According to one or more embodiments of the present disclosure, a size of the plurality of hole patterns of the second plate can be the largest in an inner periphery of one of the non-folding areas of the second plate, and gradually decrease from the inner periphery toward an outer periphery.

According to one or more embodiments of the present disclosure, the plurality of hole patterns can have oval shape, rectangular shape, rhombus shape, or circular shape.

According to one or more embodiments of the present disclosure, the plurality of groove patterns can be formed on a surface of the supporting substrate facing the display panel.

According to one or more embodiments of the present disclosure, each of the folding area and the non-folding area can comprise a display area and a non-display area.

A display apparatus according to one or more embodiments of a present disclosure can comprise a display panel including a folding area and a non-folding area adjacent to the folding area, a supporting substrate disposed below the display panel, and an adhesive layer disposed between the display panel and the supporting substrate. The supporting substrate can include a plurality of hole patterns or a plurality of groove patterns corresponding to the non-folding area.

According to one or more embodiments of the present disclosure, the supporting substrate can include a plurality of opening patterns corresponding to the folding area.

According to one or more embodiments of the present disclosure, the display apparatus can further comprise a restoration member disposed in at least one of the plurality of hole patterns or the plurality of groove patterns. The restoration member can include a polymer in which shape memory materials are dispersed.

It will be apparent to those skilled in the art that various modifications and variations can be made in the present disclosure without departing from the scope of the present disclosure. Thus, it is intended that the present disclosure cover the modifications and variations of this disclosure, provided they come within the scope of the appended claims and their equivalents.

What is claimed is:

1. A display apparatus, comprising:
a display panel including a folding area and a non-folding area adjacent to the folding area; and
a supporting substrate disposed below the display panel,
wherein the supporting substrate includes a plurality of opening patterns corresponding to the folding area and a plurality of hole patterns or a plurality of groove patterns corresponding to the non-folding area.

2. The display apparatus of claim 1, further comprising:
a first plate disposed below the display panel; and
a first adhesive layer disposed between the display panel and the first plate.

3. The display apparatus of claim 2, further comprising:
a second plate disposed below the first plate; and
a second adhesive layer disposed between the first plate and the second plate.

4. The display apparatus of claim 3, further comprising:
a third adhesive layer disposed between the second plate and the supporting substrate.

5. The display apparatus of claim 4, wherein the first, the second, and the third adhesive layers include a transparent adhesive layer, and
wherein the transparent adhesive layer includes an optically cleared resin (OCR) or an optically cleared adhesive (OCA).

6. The display apparatus of claim 1, further comprising:
a polarization film disposed above the display panel;
a touch panel disposed above the polarization film; and
a cover window disposed above the touch panel.

7. The display apparatus of claim 6, further comprising:
a fourth adhesive layer disposed between the display panel and the polarization film;
a fifth adhesive layer disposed between the polarization film and the touch panel; and
a sixth adhesive layer disposed between the touch panel and the cover window.

8. The display apparatus of claim 1, further comprising:
a touch panel disposed above the display panel;
a polarization film disposed above the touch panel; and
a cover window disposed above the polarization film.

9. The display apparatus of claim 8, further comprising:
a fourth adhesive layer disposed between the display panel and the touch panel;
a fifth adhesive layer disposed between the touch panel and the polarization film; and
a sixth adhesive layer disposed between the polarization film and the cover window.

10. The display apparatus of claim 1, further comprising:
a restoration member disposed in at least one of the plurality of hole patterns or the plurality of groove patterns,
wherein the restoration member includes a polymer in which shape memory materials are dispersed.

11. The display apparatus of claim 10, wherein the shape memory materials are formed of silver nano wire.

12. The display apparatus of claim 10, wherein the polymer is configured by an acrylic based material or silicone based material.

13. The display apparatus of claim 1, wherein the supporting substrate includes a metal material or a polymer, and
wherein the metal material includes at least one of iron (Fe), aluminum (Al), magnesium (Mg), a stainless steel, and a stainless steel including nickel (Ni).

14. The display apparatus of claim 10, wherein the shape memory materials are dispersed in the polymer with a content of about 20% to 35%.

15. The display apparatus of claim 1, wherein an area ratio occupied by one of the plurality of hole patterns to an entire area of a corresponding non-folding area among the non-folding areas is about 65% to 80%.

16. The display apparatus of claim 1, wherein each of at least one of the plurality of hole patterns has a circle shape, a rhombus shape, a square shape, or a hexagonal shape.

17. The display apparatus of claim 1, wherein at least one of the plurality of hole patterns or the plurality of groove patterns is uniformly disposed in a corresponding non-folding area among the non-folding areas.

18. The display apparatus of claim 1, wherein at least one of the plurality of hole patterns or the plurality of groove patterns has a same size over an entire surface of a corresponding non-folding area among the non-folding areas.

19. The display apparatus of claim 1, wherein at least one of the plurality of hole patterns or the plurality of groove patterns is disposed only at a periphery of one of the non-folding areas of the supporting substrate.

20. The display apparatus of claim 1, wherein at least one of the plurality of hole patterns or the plurality of groove patterns is disposed only at an inner periphery of one of the non-folding areas of the supporting substrate.

21. The display apparatus of claim 1, wherein at least one of the plurality of hole patterns or the plurality of groove patterns is disposed only in a middle portion of one of the non-folding areas of the supporting substrate.

22. The display apparatus of claim 1, wherein a size of at least one of the plurality of hole patterns or the plurality of groove patterns decreases from a middle portion to a left portion and a right portion with respect to one of the non-folding areas of the supporting substrate.

23. The display apparatus of claim 1, wherein a size of at least one of the plurality of hole patterns or the plurality of groove patterns decreases from a middle portion to four-side peripheries with respect to one of the non-folding areas of the supporting substrate.

24. The display apparatus of claim 1, wherein a size of at least one of the plurality of hole patterns or the plurality of groove patterns increases from a middle portion to a left portion and a right portion with respect to one of the non-folding areas of the supporting substrate.

25. The display apparatus of claim 1, wherein a size of at least one of the plurality of hole patterns or the plurality of groove patterns increases from a middle portion to four-side peripheries with respect to one of the non-folding areas of the supporting substrate.

26. The display apparatus of claim 1, wherein a size of at least one of the plurality of hole patterns or the plurality of groove patterns is the largest in an inner periphery of one of the non-folding areas adjacent to the folding area of the supporting substrate, and gradually decreases from the inner periphery to an outer periphery.

27. The display apparatus of claim 1, wherein a density of at least one of the plurality of hole patterns or the plurality of groove patterns is the largest in an inner periphery of one of the non-folding areas adjacent to the folding area of the supporting substrate, and gradually decreases from the inner periphery to an outer periphery.

28. The display apparatus of claim 3, wherein the second plate includes a plurality of hole patterns corresponding to one of the non-folding areas.

29. The display apparatus of claim 28, further comprising a restoration member disposed in the plurality of hole patterns of the second plate,
wherein the restoration member includes a polymer in which shape memory materials are dispersed.

30. The display apparatus of claim 28, wherein a size of the plurality of hole patterns of the second plate is the largest in an inner periphery of one of the non-folding areas of the second plate, and gradually decreases from the inner periphery to an outer periphery.

31. The display apparatus of claim 1, wherein the plurality of hole patterns have oval shape, rectangular shape, rhombus shape, or circular shape.

32. The display apparatus of claim 1, wherein the plurality of groove patterns are formed on a surface of the supporting substrate facing the display panel.

33. The display apparatus of claim 1, wherein each of the folding area and the non-folding area comprises a display area and a non-display area.
